(19) United States
(12) Patent Application Publication
(10) Pub. No.: US 2015/0185382 A1
(43) Pub. Date: Jul. 2, 2015

(54) COMPOSITE FILM HAVING SUPERIOR OPTICAL AND SOLAR PERFORMANCE

(71) Applicant: Saint-Gobain Performance Plastics Corporation, Aurora, OH (US)

(72) Inventors: Charles Leyder, Paris (FR); Anirban Dhar, Aubervilliers Cedex (FR); Claire Thoumazet, Paris (FR)

(21) Appl. No.: 14/578,742

(22) Filed: Dec. 22, 2014

Related U.S. Application Data
(60) Provisional application No. 61/922,413, filed on Dec. 31, 2013.

(51) Int. Cl. G02B 5/28; C23C 14/14; C23C 14/08; G02B 1/14; C23C 28/00

(52) U.S. Cl. CPC G02B 5/282; G02B 1/14; C23C 28/32; C23C 14/08; C23C 14/14

(57) ABSTRACT

The present disclosure is directed to transparent infra-red (IR) reflective and/or low emissivity composite films which contain an ALD metal oxide based layer. Specific embodiments of the present disclosure are directed to an IR reflective composite film comprising: a transparent substrate layer comprising a polymer; one or more metal based layers; one or more silver based layers; one or more metal oxide based layers; and an ALD metal oxide based layer.

### CROSS-REFERENCE TO RELATED APPLICATION(S)

The present application claims priority from U.S. Provisional Patent Application No. 61/922,413, filed Dec. 31, 2013, entitled “COMPOSITE FILM HAVING SUPERIOR OPTICAL AND SOLAR PERFORMANCE,” naming inventors Charles Leyder, Anirban Dhar, and Clair Thoumazet, and said provisional application is incorporated by reference herein in its entirety for all purposes.

### FIELD OF THE DISCLOSURE

The present disclosure relates to infra-red reflecting transparent composites, and more particularly to, infra-red reflecting transparent composites containing an ALD metal oxide based layer.

### RELATED ART

Composites that reflect radiation in the infrared spectrum while transmitting radiation in the visible spectrum have important applications for example as coverings applied to windows in building or vehicles.

For such composite films, visual light transmittance must be high, and the reflectivity and absorptivity must be low. In the United States of America for example, automotive windshields must have a transmittance of visible light of at least 70%. In the infrared, however, the window must have high reflectivity and so transmittance and absorptivity in the infrared must be low. Ideally the reflectivity must be high in the near infrared part of the spectrum (780 nm-2500 nm) to prevent heating from the sun light and high in the far infrared (8 μm-50 μm) to keep heat inside of a car in winter. The latter feature is also called “low-emissivity”. These combine features are of great importance especially under temperate climates.

It has been known to use thin silver layers in composite films to reflect infrared radiation; however, such silver layers have a low stability, low durability and poor moisture and weather resistance. Additionally, further layers that can be added to the composite generally negatively affect other properties such as visual light transmittance, haze, and yellowing. For example, it has been necessary in the art to use a “counter substrate” in addition to a standard substrate to sandwich and protect the silver layers. Such a counter substrate was necessary due to corrosion of the silver layer by chemical agents such as Cl, S, and others. However, using a counter substrate limits the optical and energetic performances of the composite. For example it decreases the light transmission in the visible part and suppresses totally a low emissivity feature.

As such, a need exists for composites which have superior combined infrared reflective properties both in the near and far infrared and has superior visual light transmissive composites while maintaining or improving durability and resistance to corrosion and weathering.

### BRIEF DESCRIPTION OF THE DRAWINGS

Embodiments are illustrated by way of example and are not limited in the accompanying figures.

FIG. 1 includes an illustration of a composite film according to one embodiment of the present disclosure.

FIG. 2 includes an illustration of another composite film according to one embodiment of the present disclosure.

FIG. 3 includes an illustration of another composite film according to one embodiment of the present disclosure.

FIG. 4 includes an illustration of another composite film according to one embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive- or and not to an exclusive- or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the solar control film arts.

The present disclosure describes composite films and methods of making composite films in which the composite films include an ALD metal oxide based layer. The current inventors surprisingly discovered that the addition of an ALD metal oxide based layer in a solar control film provides significantly improved properties such as visual light transmittance, total solar energy rejection, solar heat gain coefficient, light to solar gain ratio, visual light reflectance, low emissivity, abrasion resistance rating, and resistance to degradation/weathering/durability, and particularly, combinations of these properties. The concepts are better understood in view of the embodiments described below that illustrate and do not limit the scope of the present invention.

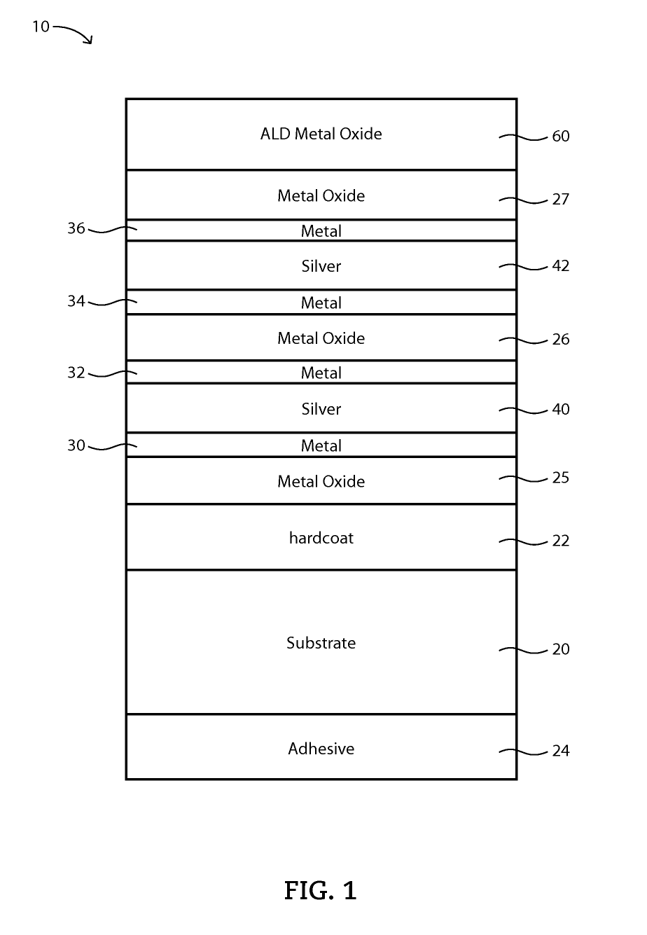

FIG. 1 illustrates a cross section of a composite film 10 according to one embodiment of the present disclosure. The composite film 10 can include a substrate layer 20, one or more metal based layers 30, 32, 34, 36, one more silver based layers 40, 42, one or more metal oxide based layers 25, 26, 27 and an ALD metal oxide based layer 60. It is to be understood that the composite film 10 illustrated in FIG. 1 is an illustrative embodiment. All of the layers shown are not required, and any number of additional layers, or less layers than shown is within the scope of the present disclosure.

The substrate layer 20 can be composed of any number of different materials. In certain embodiments, the substrate layer 20 can be a transparent layer. The substrate layer 20 can also be flexible. Suitable transparent materials include polycarbonate, polyacrylate, polyester, such as polyethylene terephthalate (PET), cellulose triacetated (TCA or TAC), polyurethane, fluoropolymers, glass, or combinations thereof. In particular embodiments, the substrate layer 20 can contain polyethylene terephthalate (PET).

The substrate layer 20 can have a thickness of at least about 0.1 micrometer, at least about 1 micrometer, or even at least about 10 micrometers. In further embodiments, the substrate layer 20 can have a thickness of no greater than about 1000 micrometers, no greater than about 500 micrometers, no greater than about 100 micrometers, or even no greater than about 50 micrometers. Moreover, the substrate layer 20 can have a thickness in a range of any of the maximum and minimum values described above, such as, from about 0.1 micrometers to about 1000 micrometers, from about 1 micrometer to about 100 micrometers, or even, from about 10 micrometers to about 50 micrometers. In other embodiments, when using a rigid substrate, such as glass, the substrate layer 20 can have a greater thickness, such as from 1 millimeter to 50 millimeters, or even 1 millimeter to 20 millimeters.

When used as a composite film for application to a rigid surface, such as a window, the substrate layer 20 can be adapted to be disposed adjacent a surface to be covered with the film. For example, when attached to, for example, a window (not shown), the substrate layer 20 can be nearer the window than an ALD metal oxide based layer 60. Moreover, as will be discussed in more detail below, an adhesive layer can be disposed adjacent the substrate layer 20 and adapted to adhere the window or other surface to be covered with the composite.

Referring again to FIG. The composite can further contain one or more metal based layers 30, 32, 34, 36. Any number of metal based layers can be included in the composite. Generally, the metal based layers may be disposed directly adjacent one or both major surfaces of a silver based layer. As such, when more than one silver based layer is present, a metal based layer can be disposed on every available major surface of any silver based layer. A thin, substantially transparent, metal based layer, such as described herein, can provide increased stability and durability of the silver containing layers and avoid intermixing at the interface of the silver based layers and the metal oxide based layer(s).

Referring again to FIG. 1, in particular embodiments of the present disclosure, a composite can contain a first metal based layer 30 and a second metal based layer 32 directly contacting opposing major surfaces of a first silver based layer 40. As further illustrated in FIG. 1, the composite can additionally contain a third metal based layer 34 and a fourth metal based layer 36 directly contacting opposing major surface of the second silver based layer 42. It is to be understood that a metal based layer may be disposed directly adjacent one or both major surfaces of any number of silver based layers that may be present in the composite.

Any of the one or more metal based layers described herein can consist essentially of a metal. As used herein, the phrase “consisting essentially of a metal” refers to at least 95 atomic % of a metal. Moreover, in particular embodiments, any of the one or more metal based layers described herein can contain an essentially pure metal or in other embodiments, a metal alloy. As used herein, “essentially pure metal” refers to a metal having and possible impurities in an amount of less than about 5 atomic %. In other embodiments, any of the one or more metal based layers can contain a metal alloy, such as for example containing a predominant metal in a concentration of at least about 70 atomic %, and a minor metal in a concentration of less than about 30 atomic % based on the total weight of the metal based layer.

Any of the one more metal based layers described herein can contain a metal including gold, titanium, aluminum, platinum, palladium, copper, indium, zinc or combinations thereof. In certain embodiments, any one of the one more metal based layers described herein can contain gold. In other particular embodiments, the metal based layer(s) can be essentially free of gold. As used herein, the phrase “essentially free of gold” refers to a metal based layer containing less than about 10 atomic % gold. In further embodiments, the metal based layer can contain less than about 5 atomic % gold, less than about 2 atomic % gold, less than about 1 atomic % gold.

As described in U.S. Pat. No. 7,709,095, gold has been the metal of choice is protecting the silver based layer from oxidation without reducing transparency. However, gold is a very expensive metal and it is desired to lessen the use of gold to lessen the cost of the composite. The current inventors have surprisingly discovered that by, for example, including an ALD metal oxide based layer, one or more or even all of the metal based layers can be essentially free of gold, and still equivalently perform the combined corrosion protection and transparency function normally only achievable by using pure or relatively pure gold.

Any of the one or more metal based layers described above can have a thickness that enables the metal based layers to be substantially transparent and provide sufficient protection to the silver based layer. In particular embodiments, any of the one or more metal based layers can be continuous such that the layer completely covers an adjacent layer, such as the silver based layer. For example, any of the one or more metal based layers described above can have a thickness of at least about 0.1 nanometers, at least about 0.5 nanometers, or even at least about 1 nanometer. Further, any of the one or more metal based layers described above can have a thickness of no greater than about 100 nanometers, no greater than about 55 nanometers, no greater than about 5 nanometers, or even no greater than about 2 nanometers. Moreover, any of the one or more metal based layers described above can have a thickness in a range of any of the maximum and minimum values described above, such as, from about 0.05 nanometers to about 5 nanometers, or even from about 0.1 nanometers to about 1 nanometer.

Any of the one or more metal based layers described above can have the same thicknesses or can have a different thickness. In particular embodiments, each of the one or more metal layers have the substantially the same thickness. As used herein, “substantially the same thickness” refers to a thicknesses that are within 20% of each other.

The metal based layer(s) can be formed by any known technique, such as a vacuum deposition technique, for example, by sputtering or evaporation.

As described above, the composites can contain one or more silver based layers. A silver based layer can provide the composite with the ability to reflect infra-red radiation both in the near infra-red and far infra-red. In particular embodiments, for example, as illustrated, in FIG. 1 the composite contain a first silver based layer 40 disposed between the ALD metal oxide based layer 60 and the substrate layer 20. As illustrated, the first silver based layer 40 can directly contact one or more metal based layers, such as a first metal based layer 30 and second metal based layer 50.

Further, in certain embodiments, the composite can contain additional silver based layers, such as a second silver based layer 42. When present, each additional silver based layer can have a metal based layer that directly contacts the major surfaces of the additional silver based layer. For example, as illustrated in FIG. 1, second silver based layer 42 can be in direct contact with a third metal based layer 34 and a fourth metal based layer 36. Further, the second silver based layer 42 can be nearer the ALD metal oxide based layer 60 than the first silver based layer 40. Any number of silver based layers and corresponding metal layers can be included. In particular embodiments, the composite can contain no more than 2 silver based layers. In other embodiments, the composite can contain no more than 3 silver based layers, or even no more than 4 silver based layers. One particular advantage of certain embodiments of the present disclosure is the ability to achieve the performance properties described herein in a composite containing no more than 2 silver based layers.

Any of the one or more silver based layers described above can contain silver, and in particular embodiments can consist essentially of silver. As used herein, the phrase “consist essentially of silver” refers to a silver based layer containing at least about 95 atomic % silver. In other embodiments, the one or more silver based layer can have no greater than about 30 atomic %, no greater than about 20 atomic %, or even no greater than about 10 atomic % of another metal, such as, gold, platinum, palladium, copper, aluminum, indium, zinc, or combinations thereof.

Any of the one or more silver based layer(s) can have a thickness of at least about 0.1 nanometers, at least about 0.5 nanometers, or even at least about 1 nanometer. Furthermore, any of the one or more silver based layer 40 can have a thickness of no greater than about 100 nanometers, no greater than about 50 nanometers, no greater than about 25 nanometers, or even no greater than about 20 nanometers. Moreover, any of the one or more silver based layer 40 can have a thickness in a range of any of the maximum and minimum values described above, such as from about 0.5 nanometers to about 25 nanometers, or even from about 1 nanometer to about 20 nanometers.

In particular embodiments, the second silver based layer 42 can have a greater thickness than the first silver based layer 40. For example, a ratio of the thickness of the second silver based layer 42 to the thickness of the first silver based layer 40 can be at least about 1, at least about 1.5, at least about 2, or even at least about 3.

The silver based layer(s) can be formed by any known technique, such as a vacuum deposition technique, for example, by sputtering or evaporation.

According to various embodiments of the disclosure, the composite can further contain one or more metal oxide based layers. For example, referring to FIG. 1, the composite can contain a first metal oxide based layer 25, a second metal oxide based layer 26, and a third metal oxide based layer 27. Generally, the metal oxide based layer can be disposed adjacent to, or even, directly contacting a major surface of a metal based layer opposite the silver based layer.

Any of the one or more metal oxide based layer(s) discussed above can contain a metal oxide such as titanium oxide, aluminum oxide, BiO₂, PbO, NbO, SnZnO, SnO₂, SiO₂, or combinations thereof. In particular embodiments, a metal oxide based layer can contain and even be substantially composed of titanium oxide. In other embodiments, a metal oxide based layer can contain and even be substantially composed of aluminum oxide.

Furthermore, the metal oxide used in the one or more metal oxide based layer(s) can have a high refractive index. For example, the metal oxide can have a refractive index of at least about 2.3, at least about 2.4, at least about 2.5 at either 510 nanometers or at 550 nanometers. For example, titanium oxide mainly composed of rutile phase has a refractive index of 2.41 at 510 nm, BiO₂ has a refractive index of 2.45 at 550 nanometers, and PbO has a refractive index of 2.55 at 550 nanometers.

In certain embodiments, the one or more metal oxide based layer(s) discussed herein can be formed by a vacuum deposition technique, for example, by sputtering or evaporation. For example, the metal oxide based layer(s) can be formed by DC magnetron, pulsed DC, dual pulsed DC, or dual pulsed AC sputtering using rotatable ceramic metal oxide targets. These targets can have enough electrical conductivity to be used as cathodes in a DC magnetron sputtering process. Further, as will be described in more detail below, any one or all of the one or more metal oxide based layers discussed herein can be formed by an atomic layer deposition technique.

When a metal oxide based layer is formed from a sputtering or evaporation technique, the metal oxide based layer(s) can have a thickness of at least about 0.5 nanometers, at least about 1 nanometer, or even at least about 2 nanometers. Further, any of the one or more metal oxide based layer(s) discussed above can have a thickness of no greater than about 100 nanometers, no greater than about 50 nanometers, no greater than about 20 nanometers, or even no greater than about 10 nanometers. Moreover, any of the one or more metal oxide based layer(s) discussed above can have a thickness in a range of any of the maximum and minimum values described above, such as, from about 0.5 nanometers to about 100 nanometers, or even from about 2 nanometers to about 50 nanometers.

When a metal oxide based layer is formed from a sputtering or evaporation technique, the one or more metal oxide based layers can have varying thicknesses. For example, in one particular embodiment, the first metal oxide based layer 25, which is disposed nearer the substrate layer 20 than the other metal oxide based layers can have a thickness which is less than any other metal oxide based layer, such as the second metal oxide based layer 26 or the third metal oxide based layer 27. In certain embodiments, a ratio of the thickness of the second metal oxide based layer 26 or third metal oxide based layer 27 to the thickness of the first metal oxide based layer 25 can be at least 1, at least 1.5, at least 2, at least 2.5, at least 3, at least 4, at least 5, or even at least 6.

Referring again to FIG. 1, one or more or even all of the metal oxide based layers can be an atomic layer deposited (ALD) metal oxide based layer. The current inventors surprisingly discovered that by incorporating a metal oxide based layer formed by an atomic layer deposition technique, the composite can exhibit excellent corrosion protection, optical performance, and solar performance without sacrificing durability. Moreover, the inventors further surprisingly discovered that by using a metal oxide based layer formed by an atomic layer deposition technique enables equivalent to superior performance as a metal oxide based layer formed by a conventional sputter technique while using thinner layers and therefore less material.

Still further, the inventors surprisingly discovered that by incorporating a metal oxide based layer formed by an atomic layer deposition technique, the composite does not require a counter substrate layer to achieve the needed corrosion protection, which is traditionally disposed adjacent the silver based layer and opposite substrate layer 20, such that the two substrate layers would sandwich the one or more silver based layers. Traditional IR reflective composite films, such as disclosed in U.S. Pat. No. 7,709,095, which is incorporated herein by reference, required a second substrate layer to thereby sandwich the silver based layer, metal based layer(s), and metal oxide based layer(s) between two substrate layers. No such counter substrate is necessary when incorporating a metal oxide based layer formed by an atomic layer deposition technique, and the composite maintains equivalent or superior corrosion resistance and durability. Further the absence of a counter substrate can enable a very low emissivity. For example, the inventors surprisingly discovered that by incorporating a metal oxide based layer formed by an atomic layer deposition technique, a significantly improved emissivity can be obtained. The inventors surprisingly discovered the ability to obtain a composite having an emissivity of almost an order of magnitude less than disclosed in U.S. Pat. No. 7,709,095 without sacrificing other properties, such as corrosion resistance and resistance to weatherability.

Still even further, the inventors surprisingly discovered that by incorporating a metal oxide based layer formed by an atomic layer deposition technique, significantly superior optical properties can be obtained, without any sacrifice of durability in comparison to a composite prepared according to U.S. Pat. No. 7,709,095.

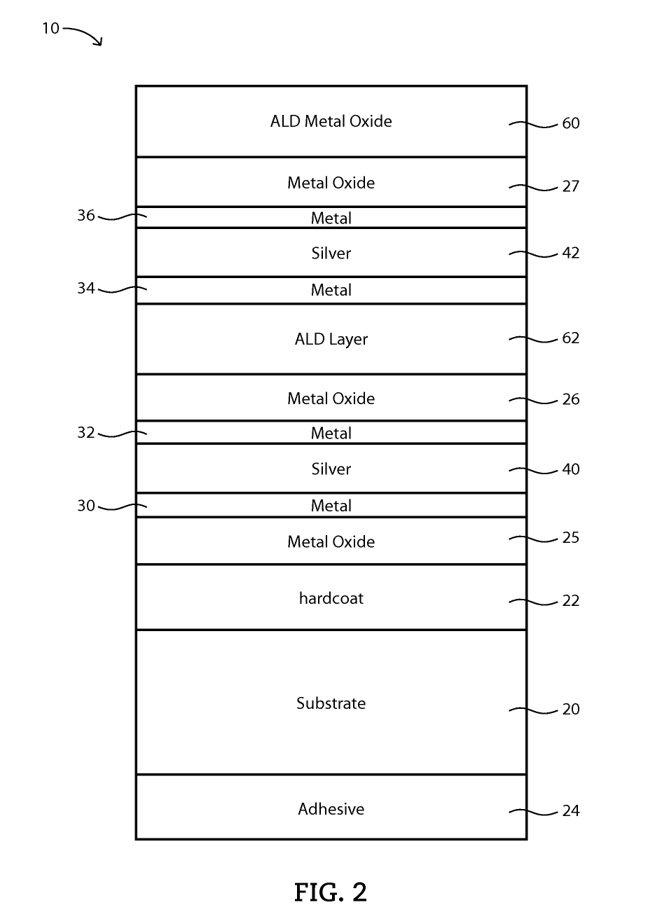

As illustrated in FIG. 1, a composite can contain an ALD metal oxide based layer 60 disposed as the uppermost metal oxide based layer (nearest to the outermost layer). It is to be understood that one, some, or all of the metal oxide based layers can be an ALD metal oxide based layer. In certain embodiments, as particularly illustrated in FIG. 2, the composite can contain more than one ALD metal oxide based layers, such as a second ALD metal oxide based layer 62. The second ALD metal oxide based layer 62 can be disposed adjacent the one or more silver based layers and opposite the first ALD metal oxide based layer, such that the first and second ALD metal oxide based layers sandwich the one or more silver layers (and even the adjacent metal layers) therebetween. In particular embodiments, first ALD metal oxide layer can directly contact the third metal based layer 34 and the second ALD metal oxide based layer 62 can directly contact the first metal oxide based layer 26.

Any of the one or more ALD metal oxide based layers can contain any of the metal oxides discussed above, and in particular can contain titanium oxide and/or aluminum oxide. In particular embodiments, the one or more ALD metal oxide based layer can be substantially composed of aluminum oxide. In other particular embodiments, the one or more ALD metal oxide based layer can be substantially composed of titanium oxide. Each of the one or more ALD metal oxide based layers can be the same or different. In particular embodiments, an outermost ALD metal oxide based layer can contain titanium oxide or aluminum oxide, and preferably titanium oxide. An inner ALD metal oxide based layer can preferably contain titanium oxide for maximizing optical benefits.

The one or more ALD metal oxide based layers can have a thickness that is less than the thickness of a metal oxide layer formed by an evaporation sputtering technique. For example, the one or more ALD metal oxide based layers can have a thickness of at least about 1 nanometer, at least about 2 nanometers, at least about 5 nanometers, or even at least about 10 nanometers. Further, the one or more ALD metal oxide based layers can have a thickness of no greater than about 200 nanometers, no greater than about 100 nanometers, no greater than about 50 nanometers, or even no greater than about 30 nanometers. Moreover, the one or more ALD metal oxide based layers can have a thickness in a range of any of the maximum and minimum values described above, such as, from about 1 nanometers to about 200 nanometers, or even about 10 nanometers to about 30 nanometers.

In particular embodiments, the first ALD metal oxide based layer 60 can have a thickness which is greater than the thickness of the second ALD metal oxide based layer 62. Further, in other embodiments, the first ALD metal oxide based layer 60 can have a thickness which is less than the thickness of the second ALD metal oxide based layer 62. In this embodiment, the first ALD metal oxide based layer 60 can be disposed further away from the substrate layer 20 than the second ALD metal oxide based layer 62.

In certain embodiments, the ALD metal oxide based layer can have a lower thickness than a metal oxide layer formed from a sputter technique. For example, a ratio of the thickness of the metal oxide layer formed from a sputtering technique to an ALD metal oxide based layer can be greater than 1, at least 1.1, at least 1.5, at least 1.8, at least 2.0, or even at least 2.5.

The composite can further include one or more adhesive layers. Referring to FIG. 1, in certain embodiments, the composite can contain an adhesive layer 24 disposed adjacent the substrate layer, and particularly, directly contacting the substrate layer. The adhesive layer 24 can be adapted to adhere the composite to a surface of a material to be covered, such as a window, visor, or the like. In certain embodiments, the adhesive layer 24 can be a pressure sensitive adhesive layer.

The adhesive layer can have a thickness of at least about 50 micrometers, at least about 100 micrometers, or even at least about 200 micrometers. Further, the adhesive layer can have a thickness of no greater than about 2000 micrometers, no greater than about 1000 micrometers, or even no greater than about 500 micrometers. Moreover, the adhesive layer can have a thickness in a range of any of the maximum and minimum values described above, such as, from about 50 micrometers to about 2000 micrometers, or even from about 200 micrometers to about 500 micrometers.

In further embodiments of the present disclosure, the composite can further include one or more additional protective layers.

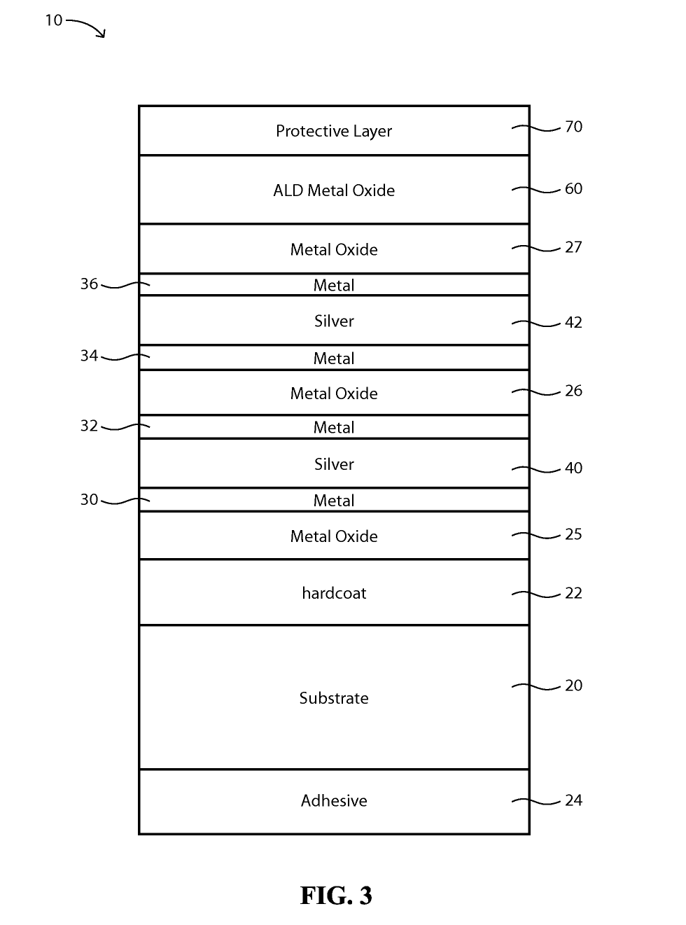

For example, as illustrated in FIG. 3, the composite can contain a fluorosilane based protective layer 70 disposed adjacent the ALD metal oxide based layer 60 opposite the one or more silver based layers 40, 42. A fluorosilane based protective layer can provide anti-smudge properties and low friction properties. For example, a fluorosilane based layer can reduce surface energy and a low coefficient of friction of the composite and thus enhance the mechanical resistance of the composite.

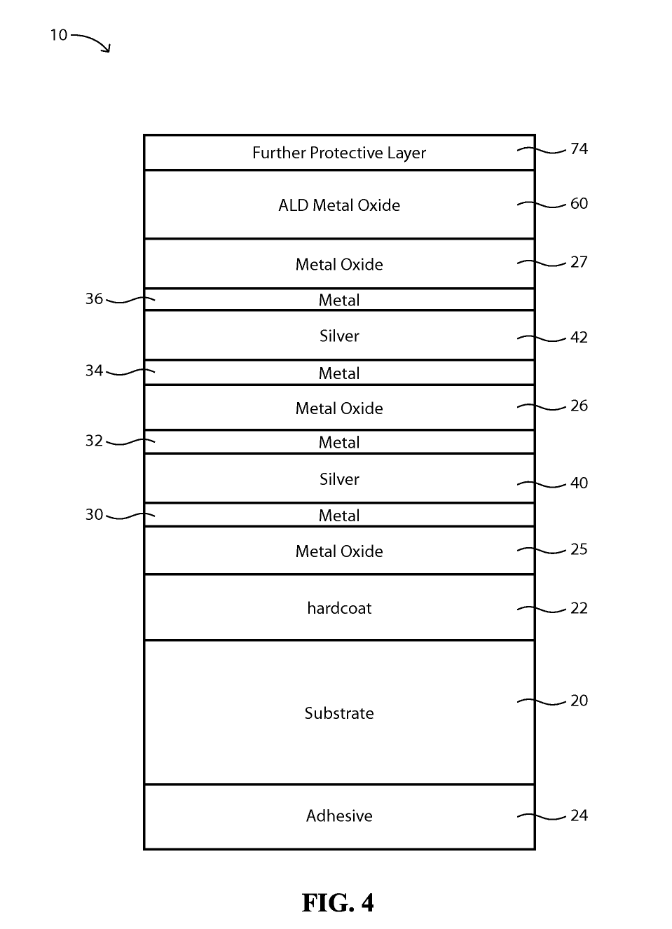

In further particular embodiments, as illustrated in FIG. 4, the composite can include a further protective layer 74 in place of, or preferably, in addition to the fluorsilane based protective layer. The further protective layer 74 can contain a SiOx, SiOxNy, or SiN. In particular embodiments, the further protective layer 74 can contain, and preferably be based on SiN. Such further protective layer 74 can provide mechanical protection to the composite.

It is to be understood that a composite can contain combinations of protective layers, such as both a flurosilane based layer and a SiN based layer.

Any of the one or more protective layers can have a thickness of at least about 0.05 micrometers, at least about 0.1 micrometers, or even at least about 0.5 micrometers. Further, any of the one or more protective layers can have a thickness of no greater than about 20 micrometers, no greater than about 10 micrometers, or even no greater than about 5 micrometers. Moreover, any of the one or more protective layers can have a thickness in a range of any of the maximum and minimum values described above, such as, from about 0.05 micrometers to about 20 micrometers, or even from about 0.5 micrometers to about 5 micrometers.

In further particular embodiments, as illustrated in FIG. 1, the composite can further include a hard coat layer 22 disposed between the substrate layer 20 and the first metal oxide based layer 25. The hard coat layer 22 can provide improvement in abrasion resistance.

In certain embodiments, the hard coat layer 22 can contain a cross-linked acrylate, an acrylate containing nanoparticles, such as SiO2, or combinations thereof.

The hard coat layer 22 can have a thickness of at least about 0.05 micrometers, at least about 0.1 micrometers, or even at least about 0.5 micrometers. Further, the hard coat layer 22 can have a thickness of no greater than about 20 micrometers, no greater than about 10 micrometers, or even no greater than about 5 micrometers. Moreover, the hard coat layer 22 can have a thickness in a range of any of the maximum and minimum values described above, such as, from about 0.05 micrometers to about 20 micrometers, or even from about 0.5 micrometers to about 5 micrometers.

Particular advantages of the composite film will now be described in terms of its performance. Parameters include visual light transmittance, total solar energy rejection, solar heat gain coefficient, light to solar gain ratio, visual light reflectance, emissivity, abrasion resistance rating, and resistance to degradation/weathering/durability.

Visual light transmittance refers to the percentage of the visible spectrum (380 to 780 nanometers) that is transmitted through a composite. The visual light transmittance can be measured according to standard ISO 9050. Although ISO 9050 refers to glazings, the same procedure can be used with a film taped or otherwise adhered to a glass window. A particular advantage of the present disclosure is the ability to obtain the visual light transmittance values described herein and illustrated in the Examples below, especially in combination with the other parameters described herein. In embodiments of the present disclosure, the composite can have a visual light transmittance of at least about 60%, at least about 65%, or even at least about 70%. Further, the composite can have a visual light transmittance of no greater than 100%, no greater than 95%, or even no greater than 90%. Moreover, the composite can have a visual light transmittance in a range of any of the maximum and minimum values described above, such as in the range of from about 60% to about 100%, or even from about 70% to about 100%.

Total Solar Energy Rejection is a measurement of the total energy rejected by a film which is the sum of the solar direct reflectance and the secondary heat transfer rejection factor towards the outside, the latter resulting from heat transfer by convection and longwave IR-radiation of that part of the incident solar radiation which has been absorbed by the film. The total solar energy rejection can be measured according to standard ISO 9050. A particular advantage of the present disclosure is the ability to obtain the total solar energy rejection values described herein and illustrated in the Examples below, especially in combination with the other parameters described herein. In particular embodiments of the present disclosure, the composite can have a total solar energy rejection of at least 30%, at least about 40%, at least about 50%, at least about 52%, at least about 55%, or even at least about 59%. Further, the composite can have a total solar energy rejection of no greater than about 90%, no greater than about 80%, or even no greater than about 70%. Moreover, the composite can have a total solar energy rejection in a range of any of the maximum and minimum values described above, such as from about 30% to about 90%, from about 50% to about 90%, or even from about 59% to about 90%.

The light to solar heat gain ratio refers to a gauge of the relative efficiency of different composite types in transmitting daylight while blocking heat gains. The higher the ratio, the brighter the room is without adding excessive amounts of heat. The light to solar heat gain ratio can be determined by the following equation:

LSHGR=(VLT)/(1−TSER)

where VLT is the visual light transmittance determined above. A particular advantage of the present disclosure is the ability to obtain the light to solar heat gain ratio values described herein and illustrated in the Examples below, especially in combination with the other parameters described herein. In particular embodiments of the present disclosure, the composite can have a light to solar gain ratio at least about 1.15, at least about 1.3, at least about 1.60, at least about 1.70, or even at least about 1.80. Further, the composite can have a light to solar gain ratio of no greater than 1.95, no greater than 1.92, or even no greater than 1.90. Moreover, the composite can have a light to solar heat gain ratio in a range of any of the maximum and minimum values described above, such as from about 1.15 to about 1.95, from about 1.60 to about 1.95, or even 1.80 to about 1.90.

The visual light reflectance is a measurement of the total visible reflected light by a glazing. The visual light reflectance can be measured according to ISO 9050. A particular advantage of the present disclosure is the ability to obtain the visual light reflectance values described herein and illustrated in the Examples below, especially in combination with the other parameters described herein. In particular embodiments of the present disclosure, the composite can have a visual light reflectance of at least about 0.5%, at least about 1%, or even at least about 2%. Further, the composite can have a visual light reflectance of no greater than about 10%, no greater than about 8%, or even no greater than about 6%. Moreover, the composite can have a visual light reflectance in a range of any of the maximum and minimum values described above, such as in the range of from about 0.5% to about 10% or even from about 2% to about 6%.

Emissivity is a measurement of the reflectivity in the far infrared (8 μm-50 μm) which indicates a composite's ability to trap heat. Emissivity can be measured according to ISO 9050. A particular advantage of the present disclosure is the ability to obtain the emissivity values described herein and illustrated in the Examples below, especially in combination with the other parameters described herein. In particular embodiments of the present disclosure, the composite can have an emissivity of no greater than about 0.9, no greater than about 0.8, no greater than about 0.7, no greater than about 0.6, no greater than about 0.5, no greater than about 0.4, no greater than about 0.3, no greater than about 0.2, or even no greater than about 0.1. Further, the composite can have an emissivity of at least 0.001, at least 0.005, or even at least 0.01. Moreover, the composite can have an emissivity in a range of any of the maximum and minimum values described above, such as in the range of from about 0.005 to about 0.8, or even from about 0.01 to about 0.5.

The abrasion resistance rating is a measurement of the ability for a glazing to sustain abrasion. The abrasion resistance rating can be measured according to Standard EN 1096-2. A particular advantage of the present disclosure is the ability to obtain the abrasion resistance rating values described herein and illustrated in the Examples below, especially in combination with the other parameters described herein. In particular embodiments of the present disclosure, the composite can have an abrasion resistance rating of at least about 50. Further, the composite can have an abrasion resistance rating of no greater than about 10 000. Moreover, the composite can have an abrasion resistance rating in a range of any of the maximum and minimum values described above, such as in the range of from about 500.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

Item 1. A substantially transparent and infra-red (IR) reflective composite film comprising an ALD metal oxide based layer.

Item 2. A composite film comprising:
a. a transparent substrate layer comprising a polymer;
b. one or more metal based layers;
c. one or more silver based layers;
d. one or more metal oxide based layers; and
e. an ALD metal oxide based layer.

Item 3. A composite film comprising:
a. a transparent substrate layer comprising a polymer;
b. one or more silver based layers;
c. one or more metal based layers in direct contact with the one or more silver layers, wherein at least one of the one or more metal based layer is essentially free of gold; and
d. an ALD metal oxide based layer.

Item 4. A composite film comprising:
a. a transparent substrate layer comprising a polymer;
b. one or more silver based layers;
c. one or more metal based layers in direct contact with the one or more silver based layers;
d. an ALD metal oxide based layer; and
e. wherein the film composite is free of a counter substrate layer.

Item 5. A composite film comprising:
a. a transparent substrate layer comprising a polymer,
b. one or more silver based layers, and
c. one or more metal oxide based layers,
d. wherein the composite has at least two of the following characteristics:
   i. a visual light transmittance (VLT) of at least at least 70%;
   ii. a light to solar heat gain ratio of greater than 1.15; and/or
   iii. an emissivity of no greater than 0.9.

Item 6. A method of forming a composite film comprising:
a. providing a transparent substrate layer comprising a polymer;
b. forming one or more metal oxide layers;
c. forming one or more metal layers;
d. forming one or more silver based layers; and
e. forming a ALD metal oxide based layer by atomic layer deposition.

Item 7. The composite or method of any one of the preceding items comprising a transparent substrate layer comprising a polymer.

Item 8. The composite or method of any one of the preceding items, wherein the transparent substrate layer comprises polycarbonate, polyacrylate, polyester, cellulose triacetated (TCA or TAC), polyurethane, or combinations thereof.

Item 9. The composite or method of any one of the preceding items, wherein the transparent substrate layer comprises polyethylene terephthalate (PET).

Item 10. The composite or method of any one of the preceding items, wherein the transparent substrate layer has a thickness of at least about 0.1 micrometers, at least about 1 micrometer, or even at least about 10 micrometers; a thickness of no greater than about 1000 micrometers, no greater than about 500 micrometers, no greater than about 100 micrometers, or even no greater than about 50 micrometers; or a thickness in a range of about 0.1 micrometers to about 1000 micrometers or even in a range of about 10 micrometers to about 50 micrometers.

Item 11. The composite or method of any one of the preceding items, wherein the composite comprises one or more metal based layers.

Item 12. The composite or method of any one of the preceding items, wherein the composite comprises a first metal based layer and a second metal based layer, and wherein the first metal based layer and the second metal based layer are in direct contact with one of the one or more silver based layer.

Item 13. The composite or method of any one of the preceding items, wherein the composite comprises a first silver based layer, a second silver based layer, a third metal based layer and a fourth metal based layer, and wherein the third metal based layer and the fourth metal based layer are in direct contact with the second silver based layer.

Item 14. The composite or method of any one of the preceding items, wherein the one or more metal based layers consist essentially of a metal.

Item 15. The composite or method of any one of the preceding items, wherein the one or more metal based layers comprises an essentially pure metal or a metal alloy.

Item 16. The composite or method of any one of the preceding items, wherein the one or more metal based layers comprise a metal selected from the group consisting of gold, titanium, aluminum, platinum, palladium, copper, indium, zinc and combinations thereof.

Item 17. The composite or method of any one of the preceding items, wherein the one or more metal based layers are essentially free of gold.

Item 18. The composite or method of any one of the preceding items, wherein the one or more metal based layers have a thickness of at least about 0.1 nanometers, at least about 0.5 nanometers, or even at least about 0.8 nanometers; wherein the layer comprising a metal has a thickness of no greater than about 50 nanometers, no greater than about 5 nanometers, no greater than about 2 nanometers, or even no greater than about 1 nanometers; or wherein the layer comprising a metal has a thickness in a range of about 0.1 nanometers to about 50 nanometers or even in a range of about 0.5 nanometers to about 1 nanometers.

Item 19. The composite or method of any one of the preceding items, wherein the composite comprises comprising one or more silver based layers.

Item 20. The composite or method of any one of the preceding items, wherein the composite comprises a first silver based layer, and a second silver based layer.

Item 21. The composite or method of any one of the preceding items, wherein the one or more silver based layers consists essentially of silver.

Item 22. The composite or method of any one of the preceding items, wherein the one more silver based layers has a thickness of at least about 0.5 nanometers, or even at least about 1 nanometers; a thickness of no greater about 100 nanometers, no greater about 50 nanometers, no greater about 25 nanometers, or even no greater about 20 nanometers; or a thickness in a range of about 0.05 nanometers to about 100 nanometers or even in a range of about 1 nanometers to about 20 nanometers.

Item 23. The composite or method of any one of the preceding items, wherein the composite comprises one or more metal oxide based layers.

Item 24. The composite or method of any one of the preceding items, wherein each of the one or more metal oxide based layers directly contacts each of the one or more metal based layer.

Item 25. The composite or method of any one of the preceding items, wherein the composite comprises a first metal oxide based layer and a second metal oxide based layer.

Item 26. The composite or method of any one of the preceding items, wherein the composite comprises a first metal oxide based layer, a second metal oxide based layer, and a third metal oxide based layer.

Item 27. The composite or method of any one of the preceding items, wherein the composite comprises a first metal oxide based layer, a second metal oxide based layer, and a third metal oxide based layer, and wherein the first metal oxide layer directly contacts a metal based layer and an adhesive layer, wherein the second metal oxide based layer directly contacts two metal based layers, and wherein the third metal oxide based layer directly contacts a metal based layer and an ALD metal oxide based layer.

Item 28. The composite or method of any one of the preceding items, wherein the one more metal oxide based layers comprise aluminum oxide, titanium oxide, BiO₂, PbO, or combinations thereof.

Item 29. The composite or method of any one of the preceding items, wherein the one ore more metal oxide based layers has a thickness of at least about 0.5 nanometers, at least about 1 nanometers, at least about 2 nanometers, or even at least about 20 nanometers; a thickness of no greater than about 100 nanometers, no greater than about 50 nanometers, no greater than about 20 nanometers, or even no greater than about 10 nanometers; or a thickness in a range of about 0.5 nanometers to about 100 nanometers or in a range of about 2-10 nanometers, or even in a range of about 20-100 nanometers.

Item 30. The composite or method of any one of the preceding items, wherein the composite comprises one or more ALD metal oxide based layers.

Item 31. The composite or method of any one of the preceding items, wherein the composite comprises a first ALD metal oxide based layer is disposed adjacent one of the one or more metal oxide based layers.

Item 32. The composite or method of any one of the preceding items, wherein the first ALD metal oxide based layer is disposed further away from the substrate layer than any of the one or more silver based layers, the one or more metal based layers, and the one or more metal oxide based layers.

Item 33. The composite or method of any one of the preceding items, wherein the composite comprises a first silver based layer and a second silver based layer, a first ALD metal oxide based layer and a second ALD metal oxide based layer, wherein the first ALD metal oxide based layer and the second ALD metal oxide based layer sandwich the first silver based layer and the second silver based layer.

Item 34. The composite or method of any one of the preceding items, wherein the ALD metal oxide based layer comprises aluminum oxide, titanium oxide, BiO₂, PbO, or combinations thereof.

Item 35. The composite or method of any one of the preceding items, wherein the ALD metal oxide based layer comprises aluminum oxide.

Item 36. The composite or method of any one of the preceding items, wherein the ALD metal oxide based layer comprises titanium oxide.

Item 37. The composite or method of any one of the preceding items, wherein the ALD metal oxide based layer comprises aluminum oxide and/or titanium oxide.

Item 38. The composite or method of any one of the preceding items, wherein an outermost ALD metal oxide based layer comprises aluminum oxide, and wherein an inner ALD metal oxide based layer comprises titanium oxide.

Item 39. The composite or method of any one of the preceding items, wherein the ALD metal oxide based layer contains a different predominant metal oxide than contained in the one more metal oxide based layers.

Item 40. The composite or method of any one of the preceding items, wherein the ALD metal oxide based layer a thickness of at least about 1 nanometers, at least about 2 nanometers, at least about 5 nanometers, or even at least about 10 nanometers; a thickness of no greater than 200 nanometers, no greater than 100 nanometers, no greater than 50 nanometers, or even no greater than 30 nanometers; or a thickness in a range of about 1 nanometers to about 200 nanometers, in a range of about 5 nanometers to about 50 nanometers, or in a range of about 10 nanometers to about 30 nanometers.

Item 41. The composite or method of any one of the preceding items, wherein the composite comprises a second adhesive layer directly contacting the substrate layer and adapted to contact a surface to be covered by the composite, such a glass layer.

Item 42. The composite or method of any one of the preceding items, wherein the adhesive layer has a thickness of at least about 50 micrometers, at least about 100 micrometers, or even at least about 200 micrometers; a thickness of no greater than 2000 micrometers, no greater than 1000 micrometers, or even no greater than 500 micrometers; or a thickness in a range of about 50 micrometers to about 2000 micrometers or in a range of about 200 micrometers to about 500 micrometers.

Item 43. The composite or method of any one of the preceding items, further comprising one or more protective layers.

Item 44. The composite or method of any one of the preceding items, further comprising a first protective layer disposed adjacent the ALD metal oxide based layer.

Item 45. The composite or method of any one of the preceding items, wherein the one or more protective layers comprise a fluorosilane.

Item 46. The composite or method of any one of the preceding items, wherein the one or more protective layers comprise a SiN.

Item 47. The composite or method of any one of the preceding items, wherein the one or more protective layers comprise a fluorosilane layer and a SiN layer.

Item 48. The composite or method of any one of the preceding items, wherein the one or more protective layers has a thickness of at least about 0.1 micrometers, or even at least about 0.2 micrometers; a thickness of no greater than 10 micrometers, no greater than 5 micrometers, or even no greater than 2 micrometers; or a thickness in a range of about 0.05 micrometers to about 10 micrometers or in a range of about 0.2 micrometers to about 2 micrometers.

Item 49. The composite of any one of the preceding items, further comprising a hard coat layer.

Item 50. The composite of any one of the preceding items, further comprising a hard coat layer disposed adjacent the ALD metal oxide layer.

Item 51. The composite of any one of any one of the preceding items, wherein the hard coat layer comprises a cross-linked acrylate.

Item 52. The composite of any one of any one of the preceding items, wherein the hard coat has a thickness of at least about 0.05 micrometers, at least about 0.1 micrometers, or even at least about 0.5 micrometers; a thickness of no greater than 20 micrometers, no greater than 10 micrometers, or even no greater than 5 micrometers; or a thickness in a range of about 0.05 micrometers to about 20 micrometers or in a range of about 0.5 micrometers to about 5 micrometers.

Item 53. The composite or method of any one of the preceding items, wherein the composite has a visual light transmittance of at least about 60%, at least about 65%, or even at least about 70%.

Item 54. The composite or method of any one of the preceding items, wherein the composite has a visual light transmittance of no greater than 100%, no greater than 95%, or even no greater than 90%.

Item 55. The composite or method of any one of the preceding items, wherein total solar energy rejection of the composite is at least about 30%, at least about 40%, at least 50%, at least about 52%, at least about 55%, or even at least about 59%.

Item 56. The composite or method of any one of the preceding items, wherein total solar energy rejection of the composite is no greater than 90%, no greater than 80%, or even no greater than 70%.

Item 57. The composite or method of any one of the preceding items, wherein the composite has a solar heat gain coefficient of at least about 0.30, at least about 0.32, or even at least about 0.35.

Item 58. The composite or method of any one of the preceding items, wherein the composite has a solar heat gain coefficient of no greater than about 0.7, no greater than about 0.5, no greater than about 0.48, or even no greater than about 0.45.

Item 59. The composite or method of any one of the preceding items, wherein the composite has a light to solar gain ratio of at least about 1.15, at least about 1.60, at least about 1.70, or even at least about 1.80.

Item 60. The composite or method of any one of the preceding items, wherein the composite has a light to solar gain ratio no greater than 1.95, no greater than 1.92, or even no greater than 1.90.

Item 61. The composite or method of any one of the preceding items, wherein the composite has a visual light reflectance of at least 0.5%, at least 1%, or even at least 2%.

Item 62. The composite or method of any one of the preceding items, wherein the composite has a visual light reflectance of no greater than 10%, no greater than 8%, or even no greater than 6%.

Item 63. The composite or method of any one of the preceding items, wherein the composite has an emissivity of no greater than about 0.9, no greater than about 0.8, no greater than about 0.7, no greater than about 0.6, no greater than about 0.5, no greater than about 0.4, no greater than about 0.3, no greater than about 0.2, or even no greater than about 0.1.

Item 64. The composite or method of any one of the preceding items, wherein the composite has an emissivity of at least 0.001, at least 0.005, or even at least 0.01.

Item 65. The method of any one of the preceding items, wherein forming the one or more metal based layers comprises a sputtering process.

Item 66. The method of any one of the preceding items, wherein forming the one or more silver based layers comprises a sputtering process.

Item 67. The method of any one of the preceding items, wherein forming the one or more metal oxide based layers comprises a sputtering process.

Item 68. The method of any one of the preceding items, wherein the one or more ALD metal oxide based layers is formed by an atomic layer deposition process.

### EXAMPLES

Samples A, B, C, and D were prepared, tested, and compared to show the significant and surprising improvement with the incorporation of an ALD metal oxide based layer. Sample A is a composite laminate according to an embodiment of the disclosure in which the composite includes an ALD titanium oxide layer disposed as the outermost layer. Sample B is a composite laminate according to an embodiment of the disclosure in which the composite includes an ALD titanium oxide layer as the outermost metal oxide layer, and a fluorosilane protective layer as an outermost layer disposed atop the titanium oxide layer. Sample C is a composite laminate according to an embodiment of the disclosure in which the composite includes an ALD metal oxide layer as an inner layer within the composite. Sample D, which is a comparative example, is commercially available from SolarGard, a division of Saint-Gobain Performance Plastics, under the trade name designation of heat-reflector LX70. In particular, Sample D does not include an ALD layer, all layers are formed from a sputtering process.

All samples were tested for performance parameters including: visual light transmittance, total solar energy rejection, solar heat gain coefficient, light to solar gain ratio, visual light reflectance, emissivity, abrasion resistance rating, and durability as described in detail above. The optical and solar measurements were performed according to ISO 9050. Although ISO 9050 relates to glazings, the same procedures and methods are used with the composite film taped or otherwise adhered to a glass window. The results are provided below in Table 1:

TABLE 1

| | | | | | | abrasion | |
|---|---|---|---|---|---|---|---|
| | | | | | | resistance | |
| Sample | VLT | TSER | LSHGR | VLR | Emissivity | rating | durability |
| A | 74.4% | 53.7% | 1.61 | 9.7 | ~4% | Good | Good |
| (with top TiOx | | | | | | | |
| ALD layer) | | | | | | | |
| B | 74.4% | 53.7% | 1.61 | 9.7 | ~4% | Excellent | Good |
| (with top TiOx | | | | | | | |
| ALD layer + | | | | | | | |
| fluorosilane) | | | | | | | |
| C | 74.4% | 53.7% | 1.61 | 9.7 | ~4% | Good | Good |
| (with | | | | | | | |
| intermediate | | | | | | | |
| TiOx ALD | | | | | | | |
| layer) | | | | | | | |
| D | 72% | 54.6% | 1.6 | 11.5 | ~89% | Good | Good |
| (Comparative- | | | | | | | |
| LX70-No | | | | | | | |
| ALD metal | | | | | | | |
| oxide layer) | | | | | | | |

As shown above, samples A-C, an ALD metal oxide layer, resulted in better optical and solar performances while unexpectedly maintaining excellent durability and providing a low emissivity.

Samples E, F, and G were prepared, tested, and compared to show the significant and surprising improvement in durability with the incorporation of an ALD metal oxide based layer. Sample E is a composite laminate according to an embodiment of the disclosure in which the composite includes an ALD titanium oxide layer disposed as the outermost layer. Sample F, which is a comparative example, is a composite laminate that is the same as Sample E except that it does not include an ALD titanium oxide layer disposed as the outermost layer. Sample G, which is also a comparative example, is a composite laminate that is the same as Sample F but with a counter substrate layer added to the stack.

All samples were tested for performance parameters including: visual light transmittance, total solar energy rejection, solar heat gain coefficient, light to solar gain ratio, visual light reflectance, emissivity, abrasion resistance rating, and durability as described in detail above. All samples were tested after 0 days of use and after 21 days of use. The optical and solar measurements were performed according to ISO 9050. Although ISO 9050 relates to glazings, the same procedures and methods are used with the composite film taped or otherwise adhered to a glass window. The durability was tested using a Neutral Salt Spray test according to EN1096-2. The results are provided below in Table 2:

TABLE 2

| | 0 days | | | | | 21 days | | | | |
|---|---|---|---|---|---|---|---|---|---|---|
| | Emissivity | VLT | VLR | TSER | | Emissivity | VLT | VLR | TSER | |
| | (%) | (%) | (%) | (%) | LSHGR | (%) | (%) | (%) | (%) | LSHGR |
| Sample E | 9.06 | 79.4 | 12.1 | 32.3 | 1.17 | 11.22 | 79.2 | 12.3 | 32.1 | 1.17 |
| (with Top | | | | | | | | | | |
| TiOx ALD | | | | | | | | | | |
| layer) | | | | | | | | | | |
| F- | 9.28 | 84.1 | 7.0 | 33.4 | 1.26 | 18.70 | 83.7 | 10.8 | 32.3 | 1.24 |
| Comparative | | | | | | | | | | |
| example (no | | | | | | | | | | |
| ALD layer) | | | | | | | | | | |
| G- | ~85 | 79.8 | 9.6 | 40.0 | 1.33 | ~85 | 79.8 | 9.6 | 40.0 | 1.33 |
| Comparative | | | | | | | | | | |
| example | | | | | | | | | | |
| (with | | | | | | | | | | |
| counter | | | | | | | | | | |
| substrate) | | | | | | | | | | |

As shown above, Sample E demonstrated an improved durability when compared to Samples F and a comparable durability when compared to Sample G. In particular, Sample F showed a much greater variation in emissivity over the 21 day period than Sample E. Further, incorporation of an ALD layer, as with Sample E, was shown to provide comparable durability to incorporation of a counter substrate layer as with Sample G and provide a low emissivity.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A substantially transparent and infra-red (IR) reflective composite film comprising an ALD metal oxide based layer.

2. The composite of claim 1, wherein the ALD metal oxide based layer comprises aluminum oxide, titanium oxide, BiO₂, PbO, or combinations thereof.

3. The composite of claim 1, wherein total solar energy rejection of the composite is at least 50% and no greater than 90%.

4. The composite of claim 1, wherein the composite has a light to solar gain ratio at least about 1.60 and no greater than 1.95.

5. The composite of claim 1, wherein the composite has a visual light reflectance of at least 0.5% and no greater than 10%.

6. A composite film comprising:
a. a transparent substrate layer comprising a polymer,
b. one or more silver based layers, and
c. one or more metal oxide based layers,
d. wherein the composite has at least two of the following characteristics:
i. a visual light transmittance (VLT) of at least at least 70%;
ii. a solar heat gain coefficient of greater than 1.6; and/or
iii. an emissivity of no greater than 0.9.

7. The composite of claim 6, wherein the transparent substrate layer comprises polycarbonate, polyacrylate, polyester, cellulose triacetated (TCA or TAC), polyurethane, or combinations thereof.

8. The composite of claim 6, wherein the transparent substrate layer comprises polyethylene terephthalate (PET).

9. The composite of claim 6, wherein the transparent substrate layer has a thickness of at least about 0.1 micrometers and no greater than about 1000 micrometers.

10. The composite of claim 6, wherein the one or more metal based layers are essentially free of gold.

11. The composite of claim 6, wherein the one more metal oxide based layers comprise aluminum oxide, titanium oxide, BiO₂, PbO, or combinations thereof.

12. The composite of claim 6, wherein the one ore more metal oxide based layers has a thickness of at least about 0.5 nanometers and no greater than about 100 nanometers.

13. The composite of claim 6, wherein the transparent substrate layer comprises polycarbonate, polyacrylate, polyester, cellulose triacetated (TCA or TAC), polyurethane, or combinations thereof.

14. The composite of claim 6, wherein the transparent substrate layer comprises polyethylene terephthalate (PET).

15. The composite of claim 6, wherein the transparent substrate layer has a thickness of at least about 0.1 micrometers and no greater than about 1000 micrometers.

16. The composite of claim 6, wherein the one or more metal based layers are essentially free of gold.

17. The composite of claim 6, wherein the one more metal oxide based layers comprise aluminum oxide, titanium oxide, BiO₂, PbO, or combinations thereof.

18. A method of forming a composite film comprising:
a. providing a transparent substrate layer comprising a polymer;
b. forming one or more metal oxide layers;
c. forming one or more metal layers;
d. forming one or more silver based layers; and
e. forming a ALD metal oxide based layer by atomic layer deposition.

19. The method of claim 18, wherein forming the one or more silver based layers comprises a sputtering process.

20. The method of claim 18, wherein the one or more ALD metal oxide based layers is formed by an atomic layer deposition process.
